(19) United States
(12) Patent Application Publication
(10) Pub. No.: US 2011/0102130 A1
(43) Pub. Date: May 5, 2011

(54) Programmable power miser

(76) Inventor: Erik Charles Rasmussen, Smithfield, ME (US)

(21) Appl. No.: 12/590,240

(22) Filed: Nov. 5, 2009

(51) Int. Cl. G05B 19/02; H05K 5/00; G05F 1/00

(52) U.S. Cl. 340/4.3; 361/679.01; 307/149

(57) ABSTRACT

The Programmable Power Miser (PPM) is a power saving and convenience device for household electronics, small appliances, and lamps The PPM enables manual or infrared controller on, off, and optionally dimming control to devices with or without a built-in infrared receiver. The PPM effectively unplugs devices to prevent them from using power when not in use, without the inconvenience of unplugging the device or using a bulky power strip. The PPM is easily programmable to recognize specific infrared signals for on-dimming, and off control, from most any source. The PPM's own infrared receiver and manual ON/OFF button are located in a discrete tethered module enabling inconspicuous placement of he components next to the device to be controlled in virtually any situation.

### CROSS REFERENCE to RELATED DUPLICATION

Not applicable

### STATEMENT REGARDING FEDERALLY SPONSORED RESEARCH or DEVELOPMENT

Not applicable

### BACKGROUND OF THE INVENTION

Many household consumer electronics and small appliances do not have an effective “off” switch.

These devices do not stop using electricity, but instead go into a “sleep mode”. In sleep mode the devices use less power than their typical “on” states, but still consume electricity at a cost to the consumer. To stop these devices from wasting power when not in use, the consumer must either unplug the device or use a switched power strip. Both means are inconvenient.

In addition, the consumer does not have the ability of adding infra-red(IR) remote control ON, OFF, and/or dimming function to a device without these features built-in.

### BRIEF SUMMARY of the INVENTION

The Programmable Power Miser (PPM) effectively unplugs electric devices to stop the consumption of electricity by that device when it is not in use. A device plugged into the PPM can be turned on, off, or dimmed either manually utilizing a tethered remote module, or via any IR controller of the consumer's choice. The controlled device need not have a built-in IR receiver. Devices such as computers and monitors without an IR receiver and with momentary contact on-off buttons will require the PPM to be turned on first, and them the actual device. However, they can still be turned off solely utilizing the PPM or IR controller.

The unique tethered remote module of the PPM allows its active components to be placed at a convenient location next to the controlled device's own on-off switch.

### BRIEF DESCRIPTION OF THE DRAWINGS

FIG. 1 A generalized view of the arrangement of the face of the wall module that plugs into a 120 v wall receptacle, and the front face of the remote module.

FIG. 2 A generalized view showing the arrangement of the top of the wall module and remote module.

FIG. 3 A generalized view showing the receptacle face of the wall module which the controlled device plugs into, and the rear face of the remote module.

FIG. 4 A generalized electrical schematic of the Programmable Power Miser with optional dimmer.

FIG. 5 Flow chart for the embedded microcontroller's main program loop.

FIG. 6 Flow chart for the embedded microcontroller's zero-crossover interrupt event subroutine.

FIG. 7 Flow chart for the embedded microcontroller's TimerO interrupt event subroutine.

### DETAILED DESCRIPTION OF THE INVENTION

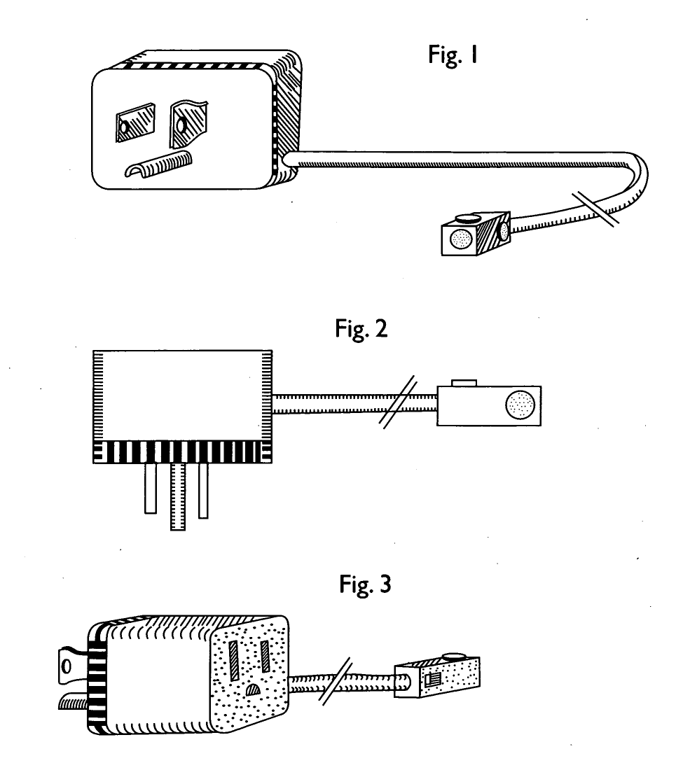

FIGS. 1, 2, and 3 show the general physical configuration of the PPM. The wall module contains the larger components, while the user interface controls are housed in the tethered remote module. The IR receiver, the on/off button, and the Program button fit into the compact remote module, along with the microcontroller in order to reduce the number of wires required to run through the tether. The compact size of remote module and the thinness of the tether, enables the remote module to be placed next to the appliance, even in tight or cluttered conditions. The tether should be six feet long to match the length of the average devices power cord.

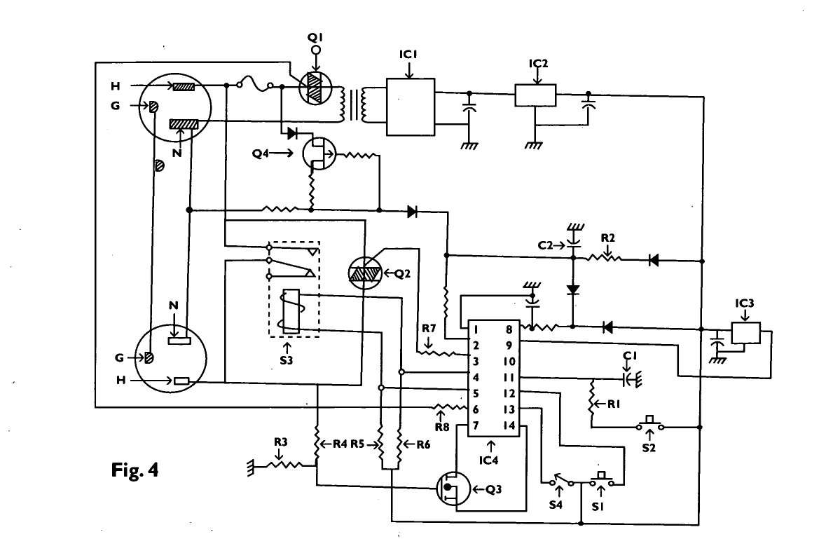

If the dimming feature is incorporated into the PPM, the housing of the wall module can include an integrated heat sink for the dimming triac Q2 (FIG. 4) if a heat sink is needed. As FIGS. 1-3 show, the heat sink can be designed to connect directly to the ground prong of the plug. The dimmer enable switch, a simple low-profile two position switch, is shown in the remote module (FIG. 3) not as part of the convenience of the remote module, but to reduce the number of wires in the tether for utility purpose, the dimmer-enable switch can go in either module. The purpose of the switch is to disable the dimming function if the PPM is to be used with a device that should not be dimmed. This switch is shown in FIG. 4 as S4, and is connected to a digital input pin on the microcontroller, shown as pin 13 on IC4. The dimmer enable switch would ordinarily be set when the device is initially plugged in, and therefore having it located in the wall module would net be an inconvenience.

To use the PPM, the state of the dimmer enable switch is selected (if dimming option is chosen for the PPM), and the wall module plugged into a 120 volt polarized and grounded wall receptacle. The controlled device's power cord is plugged into the wall module, and the remote module polarized in a convenient location.

The in/off button, and IR receiver are placed at the front of the remote module (FIG. 20) for easy access, while the program button located in a less accessible area to avoid accidental pressing. It is the programming ability of the PPM, and the remote module which make the PPM unique from other energy saving devices.

Power strips have the inconvenience of taking up a lot of work area and placing the unattractive bundle of cords in sight if one desires to have easy access to its power switch, or lace the switch on the floor. Other so-called “smart” power misers are not programmable, which differentiates them from the PPM. These devices may turn on when they detect any IR signal resulting in it needlessly being turned on whenever an IR controller is used for any other device in range. The fact that even the IR “off” signal for the controlled device would turn the other power miser on means that they have no immediate off ability as the PPM does.

The PPM can be programmed to recognize IR signals to turn it on or off. This signal can come from IR devices. The most common carrier frequency for commercial IR controllers is 38 kHz, but many inexpensive IR receivers can demodulate a broad range of carrier frequencies (1C3, FIG. 4). The demodulated signal is fed into PIN 9 of 1C4, a digital input. The source of the on and off signals can be any unused controller the consumer has, an unused button on a currently used controller, or even the same on and off buttons of the controller used for the device plugged into the PPM.

To program the PPM to an OFF signal, press and hold down the program button (S1 on FIG. 4) on the remote module. This switch connects to a digital input on 1C4. With the program button pressed, aim the IR controller to be used to turn the device off at the IR receiver at the front of the remote module (FIG. 1) for at least 0.5 seconds, then release the program button. To program the ON signal, press and hold both the program button and the on/off button (S2, FIG. 4), and repeat the process. The PPM will now respond to these signals in the future. Pressing the ON/OFF button without simultaneously pressing the program button will toggle the controlled device on or off.

If the dimming function is enabled, it does not require a separate signal or button. Holding down the ON/OFF button for one second, or holding down the button for the IC3 “ON” signal for one second, will cause the dimmer function to become active. MOSFET Q3 is sourced by the microcontroller on digital output pin 7, and read by digital input pin 14. It is triggered on and off by the 120 volt a.c. sine wave that feeds into the socket of the PPM. Resisters R3 and R4 form a voltage divider to drop the 120 volt a.c. voltage. To a level usable by the MOSFET gate.

The PPM does not require the use of specific electronic components, no an exact configuration of the circuit. What the PPM does require is: a microcontroller with EEPROM memory, or programmable FLASH memory to allow non-volatile storage of the programmed ON and OFF signals; means by which to program the PPM to recognize an IR signal; and a tethered remote module for convenience.

FIG. 4 shows a possible circuit configuration in generalized form. Specific components may require device-specific components. The circuit in FIG. 4 is a blend of low cost and low power consumption.

The microcontroller 1C4 eleven input/output pins, programmable non-volatile memory, two timers (one with an interrupt), an external source, an analogue to digital converter, and a watch dog timer (WDT). IC4 is shown to have an internal oscillator, but an external one can be used and may lead to less power usage by the PPM if the external oscillator is significantly slower than the internal one. The pins on IC4 are designed as follows.
PIN 1 GROUND
PIN 2 Analogue
PIN 3 Digital out
PIN 4 Digital out
PIN 5 Digital out
PIN 6 Digital out
PIN 7 Digital out
PIN 8 Positive operating voltage
PIN 9 Digital in
PIN 10 unused
PIN 11 Digital in
PIN 12 Digital in
PIN 13 Digital in
PIN 14 Digital in, external interrupt on falling edge

The step down transformer, rectifier IC2 should be selected for the power requirements of the circuit. Triac Q1 is used to turn off all power going to the circuit when the microcontroller is in sleep mode. Under normal conditions, the microcontroller should spend over 90% of the time in sleep mode, with no output pins sourcing power. Capacitor C2 is a super capacitor which will store electricity for the microcontroller to use while in sleep mode. Resistor R2 will be selected to allow maximum charging current to charge the super capacitor as quickly as possible. Immediately upon waking, the microcontroller will turn on Q1. The value of C2 will depend upon the power requirements of IC4 and Triac Q1 gate. These values should not exceed 30 micro amps while in sleep mode, and 20-35 milliamps while awake. The sleep cycle is ¼ second, and Q1 should trigger within 1 ms or less (depending on the oscillator speed), therefore C2 should not need to exceed 0.001 Farad.

JFET Q4 is normally conductive without a voltage on its base. Its sole purpose is to allow C2 to charge when the PPM is first plugged in, or after a power outage. The JFET should be allowed to conduct until C2 charges through R2 once. Triac Q1 is turned on. Q4 is selected as a JFET due its voltage handling capabilities, and its high base input impedance which will draw approximately 1 micro amp when turned off.

Triac Q2 is used for dimming operations. Relay S3 is for normal on-off operation. When either S3 is closed or Q2 conducting, the base of MOSFET Q3 is fed the 60 Hz AC signal through voltage divider R3 and R4. MOSFET Q3 requires virtually no current to trigger, therefore R3 and R4 can be of extremely high values to limit power use. Q3 is used to trigger the external interrupt of the microcontroller for timing the phase modulation of Triac Q2 when dimming. Since Q3 will only be used for dimming, Pin 7 of the microcontroller should remain low except when the dimming triac Q2 is active.

S3 is selected as a latching relay to eliminate the need to keep the coil energized when the PPM control device is on. Resistors R5 and R6 are pull up resistors for the relay's coil. R7 and R8 are current limiting resistors for the triac gates.

S1 is the momentary contact program button. S4 is the 2 position dimming enable switch. This switch is used to lock out the dimming ability to any device which should not dimmed. S2 is the momentary contact ON/OFF button. Capacitor C1 and R1 form a debounce subroutine included in the microcontroller's program. S1 does not need a debounce as it has to be pressed for an extended amount of time, and does not have a toggle function as ON/OFF button S2 does.

IC3 is an integrated IR receiver/demodulator, which transmits a demodulated digital signal to PIN 9 of the microcontroller. The microcontroller will monitor pin 9 for input for 3 ms. If nothing is sensed it will then conduct a sampling and conversion of analogue input pin 2 to insure the storage capacitor C2 is adequately charge. If so, Triac Q1 is turned off along with any output on pin 7, and the microcontroller returns to sleep. All unlabeled resisters and capacitors are device specific. The values of which can be found on the individual device's data sheet.

It does not matter what format the IR signal uses, as the PPM does not have to interpret it, only record it adequately for future comparison. This can be done by polling PIN 9 each 0.1-0.5 ms, and recording the state of the pin as a 16-64 bit binary number. Regardless of the manufacturer of the IR controller, each signal should consist of an idle state which is either high or low. The duration of this state should be longer than anywhere else in the data stream, therefore all the microcontroller has to do is look for the longest series of 2′s or O′s in the binary number to find the actual start of the data byte or word. The microcontroller then polls pin 9 again until it records this series, begins saving the rest of the polled results in RAM data space until the series is repeated again, and which is then stripped off. The recorded data can now be stored in nonvolatile memory as the OFF compare data or ON compare date, utilizing as many storage registers as the sampling rate and signal length requires.

The same process is repeated for checking incoming signals in the future, except that once the second reading is taken and the idle state bits stripped off, the RAM data registers are compared to the ON compare and OFF compare registers for a match.

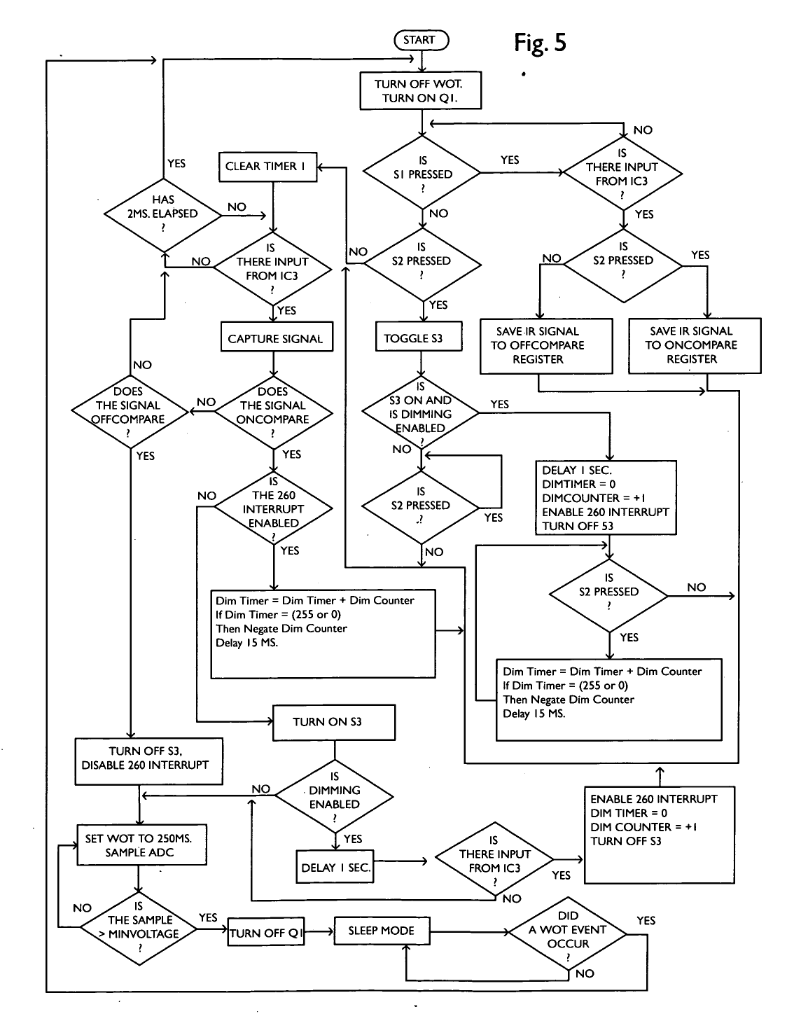

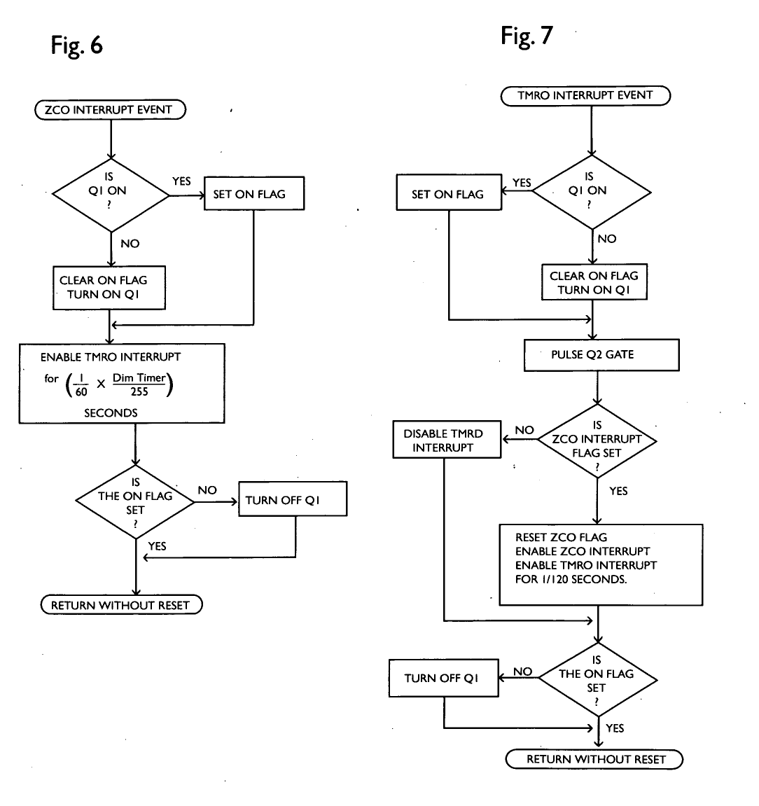

When the PPM is plugged in, the program initializes, and follow the order of flow as shown in FIGS. 5-7. Again, it is not an absolute necessity the program works exactly as shown in the flow chart, but it is to illustrate how it could be done. As you can see, ordinarily the on/off states are controlled by the locking relay, not the Triac Q2 which is pulsed on in the ZCO and TMRO interrupt event subroutines (FIG. 6-7) This adds to the cost of construction of the PPM, but results in less power usage while in use.

If dimming is enabled, any ON signal which persists for more than 1 second will result in the dimming to commence. The signal can be either an IR source or the toggling of S2 to the “ON” state. To initiate dimming, the point in time the a.c. power supply crosses from positive to zero potential must be identified. A simple zero crossover (ZCO) circuit can accomplish this, but utilizing the circuit of MOSFET Q3, and resistors R3 and R4 can work utilizing cheaper components and utilizing virtually no power. Q3 is not a true ZCO circuit as it only triggers a zero crossover from positive to negative only, but this is adequate. House hold power is typically 60 Hz, but this frequency may vary 0.5%, so a zero crossover reading is required once per period. The change is small enough that the upwards crossing will occur 1/120 second later, or half the period of the 60 Hz sine wave.

Once the initial ZCO event is enabled, variables designated Dim Timer and Dim Counter are initialized to 0 and 1 respectively. Dim Timer is used as a compare register for Time-0 (TMRO) which controls how long to delay turning on Q2 after the triac shuts off at a ZCO. Initially, there is no delay, so the controller device is at full brightness. S3 is now shut off, forcing all electricity feeding the controlled device to go through Triac Q3.

As the on signal persists, Dim Counter is added to the value in Dim Timer, causing a longer and longer delay until Q2 turns on. TMRO should be presented so that at 255 (or whatever the maximum value of Dim Timer will be), 1/120 second has passed. Upon reaching 255, the value of Dim Counter is negated to −1. Now as Dim Counter is added to Dim Timer, the delay is shorter and the device gets brighter until Dim Timer reaches zero. When Dim Timer is negated again, upon the reception of an OFF signal, both S3 and Q2 are shut off by disabling the ZCO interrupt.

1. The remote module which enables the placement of buttons and infrared receiver in a small package for ease of use without being an eyesore or causing clutter.

2. The programmability of the Programmable Power Miser to respond to infrared signals of the user's choice.

3. Optional dimming capabilities.
